(19) United States
(12) Patent Application Publication
(10) Pub. No.: US 2026/0262501 A1
(43) Pub. Date: Sep. 3, 2026

(54) Semiconductor Packaging Technique To Reduce Die Edge Stress

(71) Applicant: Google LLC, Mountain View, CA (US)

(72) Inventors: Li-Sheng Weng, San Diego, CA (US); Shu-Shen Yeh, Taipei (TW); Yung-Chang Lien, Taipei (TW); Chin Kwan Kim, San Diego, CA (US); Milind Shah, San Diego, CA (US)

(21) Appl. No.: 19/489,984

(22) PCT Filed: Jun. 6, 2024
(86) PCT No.: PCT/US2024/032865

§ 371 Date: Dec. 4, 2025

Related U.S. Application Data
(60) Provisional application No. 63/506,818, filed on Jun. 7, 2023.

(51) Int. Cl. H10W 42/00; H10W 74/10

(52) U.S. Cl. CPC H10W 42/121; H10W 74/131

(57) ABSTRACT

Systems, methods, and methods of manufacture are described for implementing a device package for an integrated circuit or packaging feature for an integrated circuit. The package includes multiple layers and a semiconductor die (102) among the multiple layers, where the semiconductor die includes multiple perpendicular comers. The package also includes a mold portion (212) along the multiple corners and the packaging feature includes a semiconductor stress reduction element (302). The mold portion encapsulates the semiconductor die and the multiple layers within the package for the integrated circuit. The semiconductor stress reduction element is: i) encompassed within the mold portion and ii) adjacent at least one corner of the multiple comers of the semiconductor die.

### BACKGROUND

This specification relates to packaging techniques for semiconductor circuit dies.

Integrated circuits can be produced using fan-out packaging techniques that implement device connectivity by redistributing connection terminals such that the device pins are fanned-out of the chip. Fanning out the terminals relative to the chip surface allows for additional input/output (I/O) connections. The semiconductor and dielectric elements are embedded or encapsulated using epoxy mold compounds that generally form an example mold-frame. A redistribution layer (RDL) can be positioned adjacent or atop the mold-frame and solder balls may be positioned at the RDL to facilitate I/O connections via a ball-grid array (BGA) pins that extend beyond a periphery of the semiconductor die.

The semiconductor is paired with a dielectric material, for example, to improve or enhance performance of the semiconductor. Generally, dielectric materials or films are used extensively in semiconductor technology for masking against the diffusion of dopants into semiconductors, fabrication of active and passive components, electrical isolation between components, and surface passivation of devices. Dielectric materials have a corresponding dielectric constant, k. The dielectric constant of a substance or material is a measure of its ability to store electrical energy and indicates the extent to which a material holds or concentrates electric flux.

### SUMMARY

This specification describes techniques for packaging silicon with other components of an integrated circuit (IC) in a manner that reduces silicon layer stress along edges or corners of a silicon die.

The IC packaging techniques leverage a stress reduction element to substantially reduce crack-inducing silicon die edge stress caused by a mismatch in thermal expansion and elastic modulus at interfaces between the silicon die and a package substrate. For example, the techniques use one or more stress reduction elements and specific positioning of those elements to homogenize thermal expansion values and elastic modulus values at the proximity or edge of an example circuit die (e.g., silicon). The homogenized values minimize (or offset) stress values at the edges or corners of a silicon die, which reduces cracking at the corresponding edges or corners.

More specifically, the disclosed techniques provide a packaging design feature that uniquely leverages a particular semiconductor material (e.g., silicon) as a stress reduction element. The stress reduction elements are positioned uniquely at a periphery of a semiconductor die to substantially reduce crack-inducing die edge stress caused by the mismatch or differences in thermal expansion and elastic modulus at interfaces between the semiconductor die and the package substrate. For example, the stress reduction elements can be placed uniquely at threshold distances from an edge or corner of a semiconductor die to achieve the reductions semiconductor die edge stress.

One aspect of the subject matter described in this specification can be embodied in a packaging feature for an integrated circuit. The package feature includes multiple layers and a semiconductor die among the multiple layers, where the semiconductor die includes multiple corners. The package feature includes a mold portion along the multiple corners, wherein the mold portion at least partially encapsulates the semiconductor die and the multiple layers within the package for the integrated circuit. The package feature includes a semiconductor stress reduction element adjacent: i) the mold portion and ii) at least one corner of the multiple corners of the semiconductor die.

These and other implementations can each optionally include one or more of the following features. For example, in some implementations, the semiconductor die includes multiple perpendicular corners and the package further includes: multiple semiconductor stress reduction elements adjacent: i) the mold portion and ii) each of the multiple perpendicular corners of the semiconductor die. The multiple semiconductor stress reduction elements can be interspersed among the mold portion when the multiple semiconductor stress reduction elements are adjacent each of the multiple perpendicular corners of the semiconductor die.

In some implementations, each semiconductor stress reduction element of the multiple semiconductor stress reduction elements is surrounded by a material that forms the mold portion when the multiple semiconductor stress reduction elements are interspersed among the mold portion. The semiconductor stress reduction element can have: i) a coefficient of thermal expansion, CTE, that is distinct from the mold portion, but that is substantially the same as the semiconductor die; and ii) an elastic modulus that is distinct from the mold portion, but that is substantially the same as the semiconductor die.

Each semiconductor stress reduction element of a first multiple semiconductor stress reduction elements can be interspersed among the mold portion to replace discrete portions of the mold portion to reduce stresses at a particular edge or corner of the semiconductor die. In some implementations, the particular semiconductor stress reduction element is adjacent at least one corner of the semiconductor die based on the particular semiconductor stress reduction element being placed at a threshold distance from the at least one edge.

In some implementations, the semiconductor stress reduction element is silicon (Si) and the threshold distance is less than or equal to 500 micrometers (μm). The semiconductor stress reduction element can be copper (Cu), and the threshold distance can be less than or equal to 500 micrometers (μm). The semiconductor stress reduction element can be a copper (Cu) pillar representing a protection non-connect via. The semiconductor stress reduction element can be a copper (Cu) pillar representing a protection interconnect via that corresponds to one or more of the multiple layers. The semiconductor stress reduction element can be silicon formed in an L-shape comprising a first portion and a second portion.

In some implementations, the semiconductor die includes multiple perpendicular corners and each of the multiple perpendicular corners includes two edge lines that intersection at a point, the two edge lines comprising a first edge line and a second edge line. The silicon formed in the L-shape is adjacent at least one perpendicular edge such that the first portion of the L-shape is parallel to the first edge line of the at least one perpendicular edge and the second portion of the L-shape is parallel to the second edge line of the at least one perpendicular edge.

Another aspect of the subject matter described in this specification can be embodied in a method of making a semiconductor device. The method includes placing a semiconductor stress reduction element adjacent: i) at least one vertex region of a semiconductor die, and ii) at least one of multiple layers. The method includes forming a mold portion along the multiple corners and along the semiconductor stress reduction element. The method also includes at least partially encapsulating, using the mold portion, the semiconductor die and the semiconductor stress reduction element within a package for the semiconductor device.

In some implementations, the method of making the semiconductor device further includes placing multiple semiconductor stress reduction elements adjacent each of multiple vertex regions of the semiconductor die. The semiconductor die can be comprised of silicon. The semiconductor stress reduction element can be formed or configured in an L-shape. In some implementations, i) a first semiconductor stress reduction element of the multiple semiconductor stress reduction elements is silicon (Si); and ii) a second semiconductor stress reduction element of the multiple semiconductor stress reduction elements is copper (Cu).

Other implementations of this and other aspects include corresponding systems, apparatus, and computer programs, configured to perform the actions of the methods, encoded on computer storage devices. A system of one or more computers can be so configured by virtue of software, firmware, hardware, or a combination of them installed on the system that in operation causes the system to perform the actions. One or more computer programs can be so configured by virtue of having instructions that, when executed by a data processing apparatus, cause the apparatus to perform the actions.

The subject matter described in this specification can be implemented in particular embodiments so as to realize one or more of the following advantages.

The disclosed techniques provide a structured fan-out packaging design framework that offsets or reduces ultra-low k (ULK) stress or extreme-low k (ELK) stress at the edges, corners, or periphery of a die (or wafer). This reduction in die edge stress can mitigate or prevent cracks in the die, which can improve reliability and extend the life of an integrated circuit. The ULK/ELK stresses are offset/reduced based on strategic placement of certain interconnect vias, such as protection interconnect vias or protection non-connect (N/C) vias, that are formed using semiconductor stress reduction elements. The elements are selected to allow for homogenizing the thermal expansion attributes and elastic modulus attributes at the proximity of a semiconductor die.

The details of one or more implementations of the subject matter described in this specification are set forth in the accompanying drawings and the description below. Other potential features, aspects, and advantages of the subject matter will become apparent from the description, the drawings, and the claims.

### BRIEF DESCRIPTION OF THE DRAWINGS

FIG. 1 is a block diagram of an example fan-out wafer-level package.

FIG. 2 is a cross-section of example elements and layers in a wafer-level package.

FIG. 3 illustrates at least a cross-section view that includes example structures for a fan-out (FO) package design.

FIG. 4 illustrates top and cross-section views that include example structures for a fan-out (FO) package design.

FIG. 5 shows normalized stress data pertaining to a first type of example structure for a fan-out (FO) package design.

FIG. 6 shows normalized stress data pertaining to a second type of example structure for a fan-out (FO) package design.

FIG. 7 is an example process or method of making a semiconductor device.

Like reference numbers and designations in the various drawings indicate like elements.

### DETAILED DESCRIPTION

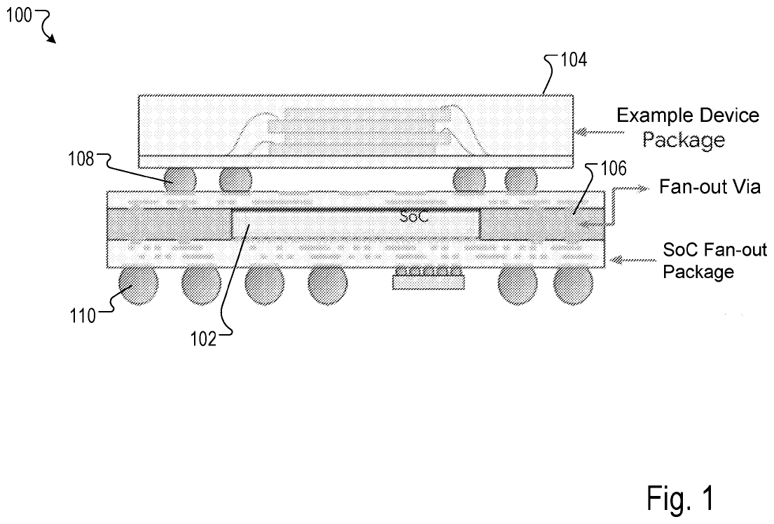

FIG. 1 is a block diagram of an example wafer-level package 100. The wafer-level package 100 is representative of an example fan-out wafer-level package (FOWLP) in which semiconductor dies are stacked and interconnected vertically within the package 100. In the example of FIG. 1, at least one semiconductor die can correspond to a hardware circuit of a System-on-Chip (“SoC”) device 102.

In some implementations, an exemplary FOWLP such as package 100 incorporates a redistribution layer (RDL) or interposer that is larger than the die as well as fan-out interconnect vias that allow for high-density interconnects. In general, this semiconductor manufacturing approach allows for incorporating large arrays of semiconductor die by housing multiple die using a stacked configuration within fan-out wafer level chip scale packages (WLCSP).

The wafer-level package 100 can represent an integrated circuit mounted on a printed circuit board (“PCB”) of an electronic or consumer device, such as a smartphone, laptop, tablet, notebook, smart speaker, network server, or gaming device. The wafer-level package 100 includes an example device package 104, multiple fan-out interconnect vias 106, and respective sets of solder balls connections 108, 110. The fan-out interconnect vias 106 and solder ball connections 108, 110 cooperate to provide electrical interconnections between the device 102, device package 104, and an example PCB where the wafer-level package 100 is ultimately mounted for installation in an example consumer device.

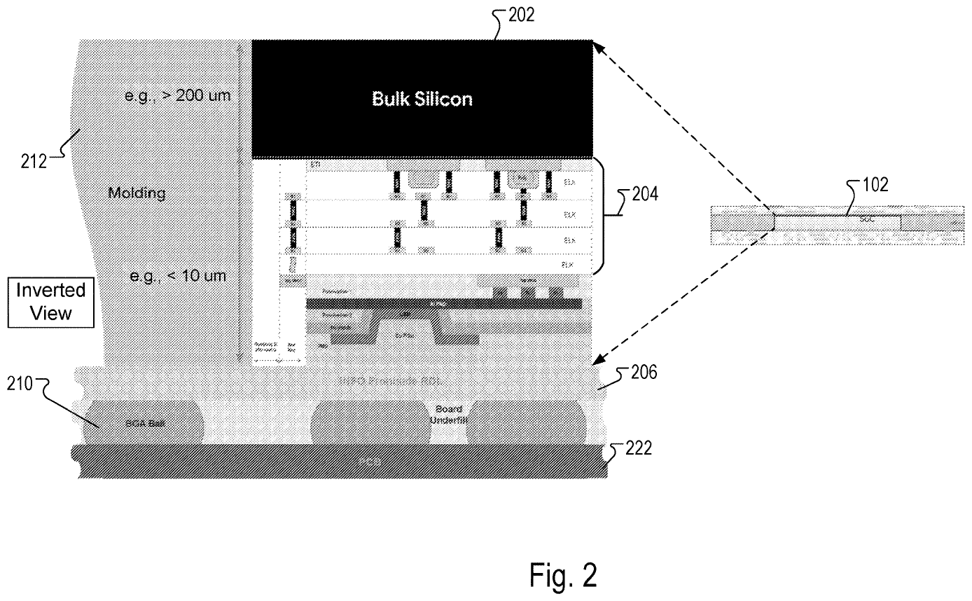

FIG. 2 is a cross-section of example elements and layers associated with device 102 in a wafer-level package 100. Included among the example elements and layers is a die 202, which can be a wafer or semiconductor die 202 upon which a circuit may be formed, such as an integrated circuit representing a chip. In the example of FIG. 2, the semiconductor die 202 is identified as silicon or bulk silicon, however other semiconductor materials or wafers can be used, such as germanium, selenium, gallium, etc.

As shown at FIG. 2, device 102 can include multiple dielectric layers 204. In some implementations, the dielectric layers 204 are composed of dielectric materials with low, ultra low, or extreme low dielectric constants, k. For example, the dielectric layers 204 can be composed of ultra low-k (ULK) dielectric materials, extreme low-k (ELK) dielectric materials, or both. As described above, a redistribution layer (RDL) 206 can be positioned adjacent the collection dielectric layers 204 and semiconductor die 202 to facilitate I/O connections via a ball-grid array (BGA) pins 210 that extend beyond a periphery of the semiconductor die 202.

The example elements and layers of device 102 are illustrated adjacent to, and contact with, a mold portion or area 212. In some implementations, the mold portion 212 is an epoxy-molding compound that surrounds, embeds, or encapsulates at least the semiconductor die 202 and dielectric layers 204 that cooperate to form an example package for device 102. Within a given device package, the semiconductor die 202 can be adjacent to, or included among, the dielectric layers 204. The semiconductor die 202 is normally a square with multiple edges and corners (or vertex regions), and the mold portion 212 can surround and/or extend along multiple edges and corners of the semiconductor die 202.

In some implementations, the mold portion 212 encapsulates the semiconductor die 202 and at least the multiple dielectric layers 204 layers within the package for the integrated circuit. In general, typical epoxy-molding compounds comprise an epoxy resin, a curing agent (hardener), a curing accelerator (catalyst), and optionally fillers and additives.

The mold portion 212 can represent a package substrate of the wafer-level package 300. The elements and layers associated with device 102 of wafer-level package 100 form the basis of an integrated circuit. As described above, the integrated circuit may be mounted on a printed circuit board 222, which is illustrated partially in the example of FIG. 2.

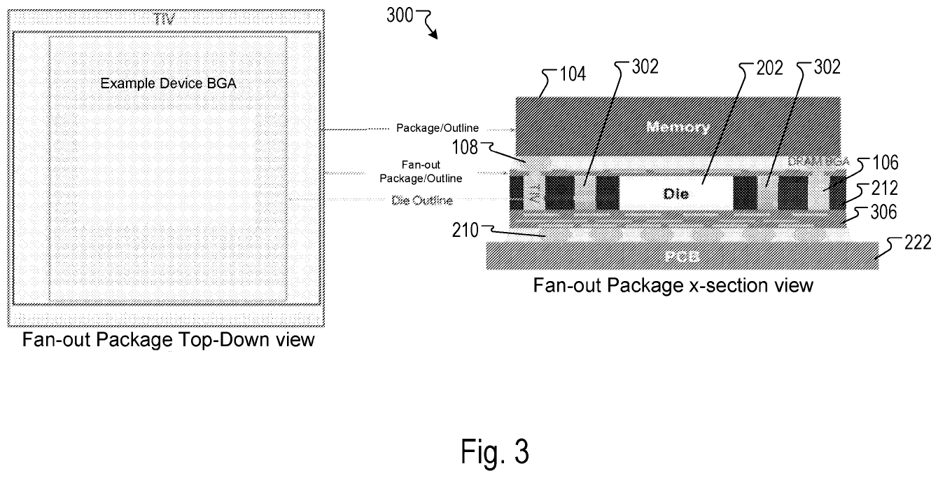

FIG. 3 illustrates a cross-section view that includes example structures for a fan-out (FO) package design or feature for a wafer-level package 300. FIG. 3 also shows a top view of wafer-level package 300. In example of FIG. 3, wafer-level package 300 is an integrated fan-out (InFO) package, however the packaging feature described with reference to wafer-level package 300 can apply to other types of fan-out packages.

In some implementations, wafer-level package 300 is an integrated fan-out package-on-package design that features a high density RDL and fan-out interconnect vias that allow for a stacked die configuration. The stacked configuration can integrate a memory circuit and a SoC (e.g., semiconductor die 202) for use in certain mobile or edge computing applications. In some implementations, the memory circuit is a random access memory (RAM) circuit, such as a static or dynamic RAM (e.g., DRAM or SRAM).

Traditionally, low dielectric constant (low-k), ultra low-k (ULK), and extreme low-k (ELK) materials are implemented in advanced semiconductor process nodes to allow for continued scaling of integrated circuit (IC) manufacturing. This continued scaling is sometimes referred to as extending Moore's Law. These ultra/extreme low-k (ULK/ELK) materials can be inorganic layers that are formed in the semiconductor manufacturing process to facilitate electrical performance of an IC device. These materials are susceptible to cracking from stresses that naturally arise due to differences in expansion and modulus attributes between the semiconductor dies and mold compounds associated with the package substrate.

More specifically, the expansion and modulus attributes are coefficient of thermal expansion and elastic modulus, respectively. In some examples, the semiconductor die is a silicon wafer with an approximate coefficient of thermal expansion (CTE) that is 3.8 PPM/° C. and an approximate elastic modulus that is 130-170 GPa. Relatedly, the mold compound associated with the package substrate is an epoxy-molding compound with an approximate CTE that is 17 PPM/° C. and an approximate elastic modulus that is 17-30 GPa. In this example the unit PPM/C is parts per million (PPM) per Celsius degree, whereas the unit GPa is Gigapascals.

Stress that results from the difference in the coefficient of thermal expansion and elastic modulus between the semiconductor die 202 and the mold portion 212 can be triggered in part from iterative heating and cooling cycles of device 102. For example, these iterative cycles can occur during normal operation of device 102, during temperature cycling testing, or both. In the example of FIG. 2, stress forces may be generated at the RDL 206 and progress toward the semiconductor die 202. However, in the example of FIG. 3, wafer-level package 300 incorporates a packaging design feature that reduces or prevents the stress at least at the edges/corners or periphery of semiconductor die 202. The packaging design feature is described in more detail below.

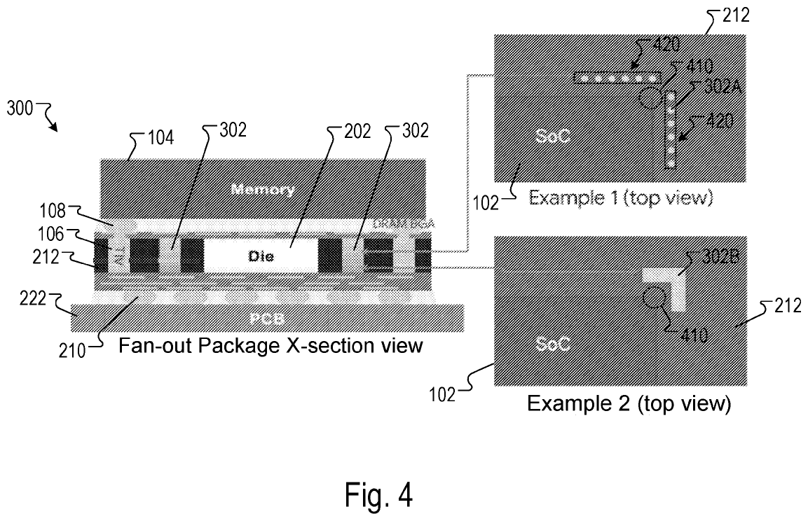

The wafer-level package 300 incorporates a packaging design feature that leverages a unique semiconductor material/element 302 as a stress reduction element. The stress reduction elements 302 are positioned uniquely at a periphery of the semiconductor die 202 to substantially reduce crack-inducing die edge stress caused by the mismatch or differences in thermal expansion and elastic modulus at interfaces between the semiconductor die 202 and the package substrate or mold portion 212. For example, the stress reduction elements 302 are placed uniquely at threshold distances from an edge or corner of semiconductor die 202. This is described in more detail below with reference to FIG. 4. Additionally, in examples, a semiconductor element 302 is described alternatively as a semiconductor stress reduction element 302.

The packaging design feature leverages CTE and modulus attributes of one or more stress reduction elements 302 to negate or offset the mismatch/differences in thermal expansion and elastic modulus that would normally trigger stress at certain interface points between semiconductor die 202 and mold portion 212. The intrinsic attributes of the stress reduction elements 302 coupled with their unique placement allows for homogenizing thermal expansion values and elastic modulus values at the proximity or edges of an example circuit die, such as semiconductor die 202. The homogenized values allow for reducing (or preventing) some or all stress at the edges or corners of a semiconductor (e.g., silicon) die, which reduces cracking at the corresponding edges or corners.

The stress reduction elements 302 can have a depth that is consistent with a depth of the semiconductor die 202. A thickness, depth, and/or overall size of a stress reduction element 302 can vary based on design preference and desired stress reduction. In some implementations, a stress reduction element 302 is sized sufficiently relative to the semiconductor die to achieve a threshold measure of stress reduction at or along an edge or corner of the semiconductor die 202.

FIG. 4 illustrates top and cross-section views that include example design structures or features for a fan-out (FO) package design.

The packaging feature of wafer-level package 300 provides a structured integrated fan-out (InFO) packaging design framework that offsets or reduces ultra-low k (ULK) stress or extreme-low k (ELK) stress at the edges, corners, or periphery of semiconductor die 202. This reduction in die edge stress mitigates or prevents cracks in semiconductor die 202, which can improve reliability and extend the life of an integrated circuit of device 102. As discussed above, the ULK/ELK stresses are offset/reduced based on strategic placement of stress reduction elements 302.

The stress reduction elements 302 can be protection fan-out interconnect vias formed using different types of semiconductor materials. More specifically, a stress reduction element 302 can be a protection non-connect (N/C) via, a protection interconnect via, or both. For example, one or more stress reduction elements 302 can be protection non-connect (N/C) vias that are not used to route electrical signals or provide an interconnection to other areas or elements of a circuit package, whereas one or more other stress reduction elements 302 can be protection interconnect vias that route electrical signals and provide interconnection to other regions or elements of a circuit package.

The protection aspect of semiconductor elements 302 corresponds to stress reduction across the semiconductor die 202 that results from the strategic placement or positioning of semiconductor elements 302 at the periphery or edge of the semiconductor die 202. As described briefly above, the semiconductor elements 302 are selected to allow for homogenized CTE and elastic modulus attributes at the proximity of a semiconductor die 202. More specifically, to achieve the desired stress reductions, the semiconductor elements 302 are placed uniquely at threshold distances from an edge or corner of the semiconductor die 202. In some implementations, the threshold distances vary based on the type of semiconductor material that is used.

For example, a first threshold distance may be selected for a first type of semiconductor material, whereas a second, different threshold distance may be selected for a second, different type of semiconductor material. In some implementations, the semiconductor material is silicon, copper, or both. In one example the threshold distance is less than or equal to 1000 micrometers (μm), whereas in another example the threshold distance is less than or equal to 500 micrometers (μm).

In the example of FIG. 4, the semiconductor die 202 is a square with multiple corners or vertex regions 410 that form a junction between edges. As shown, the semiconductor die 202 can include four corners 410 (or four perpendicular edge regions 410). The disclosed packaging design feature can include stress reduction elements 302 that are: i) adjacent the mold portion 212 and ii) adjacent each vertex region 410 of the multiple perpendicular corners/edges. In some implementations, the stress reduction elements 302 are adjacent the mold portion 212 by virtue of being entirely within and/or encompassed (or encapsulated) by the mold portion 212.

A particular stress reduction element 302 is adjacent to at least one corner/region 410 of the semiconductor die 202 based on the particular stress reduction element 302 being placed at a threshold distance from the at least one vertex region 410. In some implementations, the stress reduction elements 302 may be applied to the periphery of a non-square semiconductor die 202, such as a circular or rectangular die.

The semiconductor material for the stress reduction elements 302 is selected based on the semiconductor die 202. In some implementations, the semiconductor material for the stress reduction elements 302 is the same as (or substantially the same as) the semiconductor material for the semiconductor die 202. In some other implementations, the semiconductor material for the stress reduction elements 302 is different from the semiconductor material for the semiconductor die 202, but has the same, or substantially the same, CTE and elastic modulus attributes as the semiconductor die 202.

In some cases, the manner in which the stress reduction elements 302 are installed or integrated for a packaging design feature within the wafer-level package 300 may also vary based on the type of semiconductor material used. For example, the stress reduction elements 302 may be integrated as protection non-connect (or interconnect) pillars 302A or fan-out interconnect vias when the semiconductor material is copper. In some implementations, the stress reduction elements 302 are protection non-connect (or interconnect) pillars 302A that are arranged in one or more groupings of fan-out protection vias 420.

In some implementations, the stress reduction elements 302A are interspersed among the mold portion 212. For example, the semiconductor die 202 may be interspersed among the mold portion 212 when the stress reduction elements 302A are adjacent to one or more of the perpendicular edges 410. Additionally, the semiconductor die 202 may be interspersed among the mold portion 212 when the stress reduction elements 302A are: i) adjacent one or more of the perpendicular corner/vertex region 410; ii) arranged as one or more groupings of fan-out protection vias 420; or iii) both.

When the semiconductor material is silicon, the stress reduction elements 302 may be integrated at an edge or corner of the semiconductor die 202 using any shape. In the example of FIG. 4, the stress reduction element 302B is an L-shaped piece of silicon, however other shapes may be used and are within the scope of this specification.

In some implementations, each stress reduction element 302 is interspersed among (or within) the mold portion 212 to replace discrete portions of the mold portion 212 as a way to reduce stresses at a particular corner 410 of the semiconductor die 202. In this manner, each stress reduction element 302A, 302B can be surrounded by, or entirely encompassed within, a material that forms the mold portion 212. For example, each stress reduction element 302 can be surrounded by and/or interspersed among an epoxy-molding compound representing mold portion 212. In these and other examples, the stress reduction element 302 can be incorporated as a protection non-connect (or interconnect) pillar. In some implementations, the stress reduction element 302 is incorporated using an L-shape, whereas in some other implementations, the stress reduction element 302 is incorporated using a shape other than an L-shape.

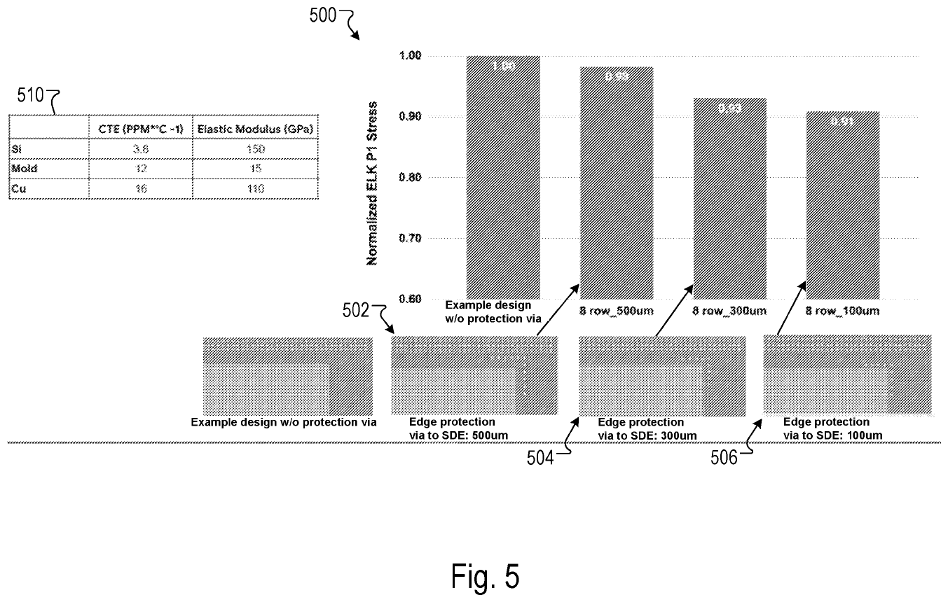

FIG. 5 shows normalized stress data 500 pertaining to a first type of example structure (e.g., stress reduction elements 302A) for a packaging design feature in a fan-out (FO) package.

The example of FIG. 5 includes: i) a first example implementation 502 where the stress reduction elements 302A are protection non-connect (or interconnect) vias that are placed 500 micrometers (μm) away from a corner 410 of the semiconductor die 202, ii) a second example implementation 504 where the stress reduction elements 302A are protection non-connect (or interconnect) vias that are placed 300 μm away from a corner 410 of the semiconductor die 202, and iii) a third example implementation 506 where the stress reduction elements 302A are protection non-connect (or interconnect) vias that are placed 100 μm away from the corner 410 of the semiconductor die 202.

These example threshold distances of 500 μm, 300 μm, and 100 μm can yield corresponding reductions in die edge ULK/ELK stress of 2%, 7% and 9%, respectively. In some implementations, a respective size of each stress reduction element 302/302A, and its corresponding spacing relative to the different corners 410 of a die edge, can be varied to achieve greater magnitudes of stress reduction.

Example CTE and elastic modulus attributes are shown at table 510. In some implementations, the semiconductor material that represents a stress reduction element 302 has: i) a coefficient of thermal expansion, CTE, that is distinct from the mold portion, but that is the same as the silicon die; and ii) an elastic modulus that is distinct from the mold portion, but that is the same as the silicon die.

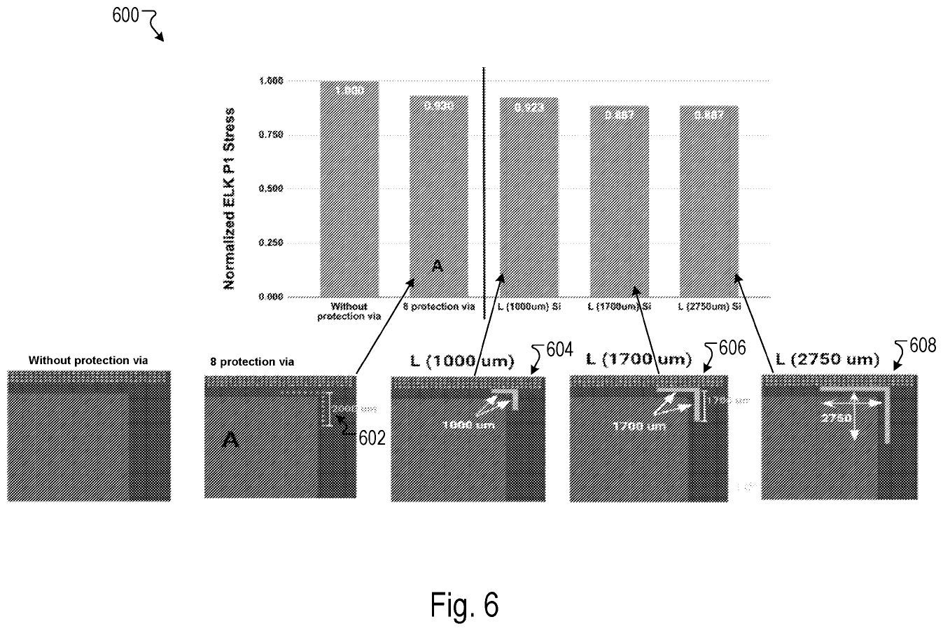

FIG. 6 shows normalized stress data 600 pertaining to a second type of example structure (e.g., stress reduction elements 302B) for a packaging design feature in a FO package. In the example of FIG. 6, the stress reduction elements 302B are L-shaped silicon portions that are placed 300 μm away from the corner 410 of the semiconductor die 202. This threshold distance can yield corresponding reductions in die edge ULK/ELK stress of 8% to 11%, by using different arm extension lengths for the L-shape.

As indicated above, the semiconductor die 202 can include perpendicular corners 410. Additionally, the stress reduction element 302 can be silicon formed in an L-shape that includes a first portion and a second portion. In some implementations, each perpendicular corner 410 comprises two edge lines that intersect at a point (e.g., a vertex region). The two edge lines can include a first edge line and a second edge line. The silicon formed in the L-shape is adjacent at least one perpendicular corner 410 such that the first portion of the L-shape is parallel to the first edge line of the at least one perpendicular corner 410 and the second portion of the L-shape is parallel to the second edge line of the at least one perpendicular corner 410.

The first portion can correspond to a first arm extension, whereas the second portion can correspond to a second arm extension. Each of the first portion and second portion includes multiple sides. In some implementations, a length of the first portion is the same as a length of the second portion. In some other implementations, a length of the first portion is different from a length of the second portion. The respective lengths may be measured along sides that correspond between the two portions.

The example of FIG. 6 includes: i) a first example implementation 602 where the stress reduction elements 302B are L-shaped elements with at least one portion having a length of at least 1000 μm and being placed in proximity to a corner 410 of the semiconductor die 202; ii) a second example implementation 604 where the stress reduction elements 302B are L-shaped elements with at least one portion having a length of at least 1700 μm and being placed in proximity to a corner 410 of the semiconductor die 202; and iii) a third example implementation 606 where the stress reduction elements 302B are L-shaped elements with at least one portion having a length of at least 2750 μm and being placed in proximity to a corner 410 of the semiconductor die 202.

Each of the first portion and the second portion can have a respective length that is greater than zero μm and less 3000 μm. Referencing the example of FIG. 6, a respective length of the first portion and/or the second portion can be 1000 μm, 1700 μm, or 2750 μm; however other lengths are within the scope of this disclosure. The shape and dimensions (e.g., length, width, height) of the stress reduction element 302 can be adjusted to achieve a desired stress profile or amount of stress reduction at different areas of the semiconductor die 202.

In some implementations, a computer system or software/firmware program is configured to generate and/or analyze different groupings or combinations of characteristics, such as shapes, dimensions, placement locations, and semiconductor materials, for stress reduction elements 302. The computer system or program can identify and select a particular grouping of characteristics that allow for achieving a desired stress profile or stress reduction. The computer system can use special-purpose circuitry or compute logic, such as hardware accelerators or machine-learning algorithms, to determine the combination of the characteristics. The computer system or programs can be also used to execute and control manufacturing processes for making a semiconductor device or packaging design feature based on different groupings or combinations of characteristics and semiconductor materials that are determined for the stress reduction elements 302.

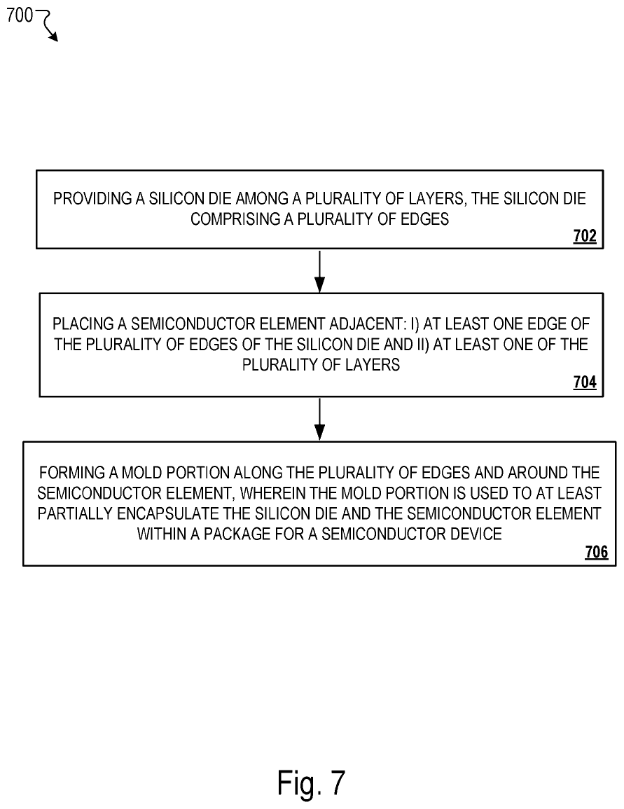

FIG. 7 is an example process or method of making a semiconductor device. Aspects of process 700 can be implemented or executed using an example computer system described herein. In some examples, the steps or actions of process 700 are enabled by programmed software instructions, firmware instructions, or both. Each type of instruction may be stored in a non-transitory machine-readable storage device and is executable by one or more processors or other computing resources described in this specification.

In some implementations, steps of process 700 can be performed using a hardware integrated circuit that implements machine-learning (ML) models. A portion of the integrated circuit can include a special-purpose processor, such as a neural network processor or hardware ML accelerator configured to accelerate computations for generating different types of data processing outputs that are associated with manufacturing processes or methods for making an example semiconductor device.

In the example of FIG. 7, process 700 includes providing a silicon or semiconductor die among multiple layers (702), such as an RDL and interposer layer or layers 204, as described above. The silicon die includes multiple edges. Process 700 includes placing a stress reduction element 302 adjacent: i) at least one edge of the multiple edges of the silicon die and ii) at least one of the multiple layers (704). In some implementations, the stress reduction element 302 is placed adjacent an edge of the silicon die by affixing or attaching the stress reduction element 302 to an interposer layer or RDL that is in close proximity to the silicon die. Process 700 further includes forming a mold portion along the multiple edges and around the stress reduction element. The mold portion is used to at least partially encapsulate the silicon die and the stress reduction element 302 within a package for the semiconductor device (706).

Embodiments of the subject matter and the functional operations described in this specification can be implemented in digital electronic circuitry, in tangibly-embodied computer software or firmware, in computer hardware, including the structures disclosed in this specification and their structural equivalents, or in combinations of one or more of them. Embodiments of the subject matter described in this specification can be implemented as one or more computer programs, i.e., one or more modules of computer program instructions encoded on a tangible non-transitory program carrier for execution by, or to control the operation of, data processing apparatus. These embodiments can include processes and methods of making or manufacturing a semiconductor device, a wafer-level package, packaging features, or package structures described in this specification.

Alternatively, or in addition, the program instructions can be encoded on an artificially generated propagated signal, e.g., a machine-generated electrical, optical, or electromagnetic signal, that is generated to encode information for transmission to suitable receiver apparatus for execution by a data processing apparatus. The computer storage medium can be a machine-readable storage device, a machine-readable storage substrate, a random or serial access memory device, or a combination of one or more of them.

The term “computing system” encompasses all kinds of apparatus, devices, and machines for processing data, including by way of example a programmable processor, a computer, or multiple processors or computers. The apparatus can include special purpose logic circuitry, e.g., an FPGA (field programmable gate array) or an ASIC (application specific integrated circuit). The apparatus can also include, in addition to hardware, code that creates an execution environment for the computer program in question, e.g., code that constitutes processor firmware, a protocol stack, a database management system, an operating system, or a combination of one or more of them.

A computer program (which may also be referred to or described as a program, software, a software application, a module, a software module, a script, or code) can be written in any form of programming language, including compiled or interpreted languages, or declarative or procedural languages, and it can be deployed in any form, including as a stand-alone program or as a module, component, subroutine, or other unit suitable for use in a computing environment.

A computer program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub programs, or portions of code. A computer program can be deployed to be executed on one computer or on multiple computers that are located at one site or distributed across multiple sites and interconnected by a communication network.

The processes and logic flows described in this specification can be performed by one or more programmable computers executing one or more computer programs to perform functions by operating on input data and generating output. The processes and logic flows can also be performed by, and apparatus can also be implemented as, special purpose logic circuitry, e.g., an FPGA (field programmable gate array), an ASIC (application specific integrated circuit), or a GPGPU (General purpose graphics processing unit).

Computers suitable for the execution of a computer program include, by way of example, can be based on general or special purpose microprocessors or both, or any other kind of central processing unit. Generally, a central processing unit will receive instructions and data from a read only memory or a random access memory or both. Some elements of a computer are a central processing unit for performing or executing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

To provide for interaction with a user, embodiments of the subject matter described in this specification can be implemented on a computer having a display device, e.g., LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

Embodiments of the subject matter described in this specification can be implemented in a computing system that includes a back end component, e.g., as a data server, or that includes a middleware component, e.g., an application server, or that includes a front end component, e.g., a client computer having a graphical user interface or a Web browser through which a user can interact with an implementation of the subject matter described in this specification, or any combination of one or more such back end, middleware, or front end components. The components of the system can be interconnected by any form or medium of digital data communication, e.g., a communication network. Examples of communication networks include a local area network (“LAN”) and a wide area network (“WAN”), e.g., the Internet.

The computing system can include clients and servers. A client and server are generally remote from each other and typically interact through a communication network. The relationship of client and server arises by virtue of computer programs running on the respective computers and having a client-server relationship to each other.

While this specification contains many specific implementation details, these should not be construed as limitations on the scope of any invention or of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In certain implementations, multitasking and parallel processing may be advantageous.

1. A packaging feature for an integrated circuit, the package feature comprising:
a plurality of layers;
a semiconductor die among the plurality of layers, the semiconductor die comprising a plurality of corners;
a mold portion along the plurality of corners, wherein the mold portion at least partially encapsulates the semiconductor die and the plurality of layers within the package for the integrated circuit; and
a semiconductor stress reduction element adjacent: i) the mold portion and ii) at least one corner of the plurality of corners of the semiconductor die.

2. The packaging feature of claim 1, wherein the semiconductor die comprises a plurality of perpendicular corners and the package further comprises:
a plurality of semiconductor stress reduction elements adjacent: i) the mold portion and ii) each of the plurality of perpendicular corners of the semiconductor die.

3. The packaging feature of claim 2, wherein the plurality of semiconductor stress reduction elements are interspersed among the mold portion when the plurality of semiconductor stress reduction elements are adjacent each of the plurality of perpendicular corners of the semiconductor die.

4. The packaging feature of claim 2, wherein each semiconductor stress reduction element of the plurality of semiconductor stress reduction elements is surrounded by a material that forms the mold portion when the plurality of semiconductor stress reduction elements are interspersed among the mold portion.

5. The packaging feature of claim 4, wherein the semiconductor stress reduction element has:
i) a coefficient of thermal expansion, CTE, that is distinct from the mold portion, but that is substantially the same as the semiconductor die; and
ii) an elastic modulus that is distinct from the mold portion, but that is substantially the same as the semiconductor die.

6. The packaging feature of claim 5, wherein each semiconductor stress reduction element of a first plurality of semiconductor stress reduction elements is interspersed among the mold portion to replace discrete portions of the mold portion to reduce stresses at a particular edge or corner of the semiconductor die.

7. The packaging feature of claim 1, wherein a particular semiconductor stress reduction element is adjacent at least one corner of the semiconductor die based on the particular semiconductor stress reduction element being placed at a threshold distance from the at least one edge.

8. The packaging feature of claim 7, wherein the semiconductor stress reduction element is silicon (Si).

9. The packaging feature of claim 8, wherein the threshold distance is less than or equal to 500 micrometers (μm).

10. The packaging feature of claim 7, wherein the semiconductor stress reduction element is copper (Cu).

11. The packaging feature of claim 10, wherein the threshold distance is less than or equal to 500 micrometers (μm).

12. The packaging feature of claim 10, wherein the semiconductor stress reduction element is a copper (Cu) pillar representing a protection non-connect via.

13. The packaging feature of claim 10, wherein the semiconductor stress reduction element is a copper (Cu) pillar representing a protection interconnect via that corresponds to one or more of the plurality of layers.

14. The packaging feature of claim 1, wherein the semiconductor stress reduction element is silicon formed in an L-shape comprising a first portion and a second portion.

15. The packaging feature of claim 14, wherein:
the semiconductor die comprises a plurality of perpendicular corners;
each of the plurality of perpendicular corners comprises two edge lines that intersection at a point, the two edge lines comprising a first edge line and a second edge line; and
the silicon formed in the L-shape is adjacent at least one perpendicular edge such that the first portion of the L-shape is parallel to the first edge line of the at least one perpendicular edge and the second portion of the L-shape is parallel to the second edge line of the at least one perpendicular edge.

16. A method of making a semiconductor device, the method comprising:
placing a semiconductor stress reduction element adjacent:
i) at least one vertex region of a semiconductor die, and
ii) at least one of a plurality of layers;
forming a mold portion along the plurality of corners and the semiconductor stress reduction element; and
at least partially encapsulating, using the mold portion, the semiconductor die and the semiconductor stress reduction element within a package for the semiconductor device.

17. The method of making the semiconductor device of claim 16, further comprising:
placing a plurality of semiconductor stress reduction elements adjacent each of a plurality of vertex regions of the semiconductor die.

18. The method of making the semiconductor device of claim 16, wherein the semiconductor die is comprised of silicon.

19. The method of making the semiconductor device of claim 16, wherein the semiconductor stress reduction element is formed or configured in an L-shape.

20. The method of making the semiconductor device of claim 17, wherein:
i) a first semiconductor stress reduction element of the plurality of semiconductor stress reduction elements is silicon (Si); and
ii) a second semiconductor stress reduction element of the plurality of semiconductor stress reduction elements is copper (Cu).
